(19) United States
(12) Patent Application Publication
(10) Pub. No.: US 2005/0282387 A1
(43) Pub. Date: Dec. 22, 2005

(54) Metal polish composition, polishing method using the composition and method for producing wafer using the polishing method

(76) Inventors: Takashi Sato, Chiba-shi (JP); Ayako Nishioka, Chiba-shi (JP); Daigo Ito, Takasaki-shi (JP)

Correspondence Address: SUGHRUE MION, PLLC, 2100 PENNSYLVANIA AVENUE, N.W., SUITE 800, WASHINGTON, DC, 20037, US

(21) Appl. No.: 10/517,149

(22) PCT Filed: Jun. 6, 2003
(86) PCT No.: PCT/JP03/07182

§ 371 Date: Jul. 25, 2005

(30) Foreign Application Priority Data
Jun. 7, 2002 (JP) 2002-166436
Jun. 14, 2002 (US) 60388301

(51) Int. Cl. C09G 1/08; H01L 21/302; H01L 21/461

(52) U.S. Cl. 438/689; 106/10

(57) ABSTRACT

A metal polish composition contains an amine represented by general formula (1): 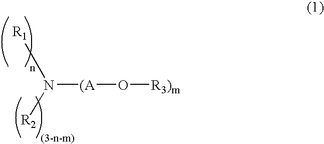 wherein m represents an integer of from 1 to 3 and n represents an integer of from 0 to 2, with m and n being such that (3-n-m) is an integer of from 0 to 2; A represents a straight-chained or branched alkylene, phenylene or substituted phenylene group having 1 to 5 carbon atoms; R1 and R3 each independently represent hydrogen or a substituted or non-substituted hydrocarbon group having 1 to 5 carbon atoms; R3 represents a substituted or non-substituted hydrocarbon group having 1 to 20 carbon atoms; a combination of R1 and R2, a combination of R2 and R3 and a combination of A and R3 can form a ring structure; and R1, R2, R3 and A can individually form a ring structure.

### CROSS REFERENCE TO RELATED APPLICATIONS

This application is an application filed under 35 U.S.C. § 111(a) claiming the benefit pursuant to 35 U.S.C. § 119(e) (1) of the filing date of Provisional Application No. 60/388,301 filed Jun. 14, 2002 pursuant to 35 U.S.C. § 111(b).

### TECHNICAL FIELD

The present invention relates to a metal polish composition with which wafers are polished, to a method for polishing wafers using the composition and to a method for producing wafers using the polishing method.

### BACKGROUND ART

Technological advances in the production of integrated circuits (IC's) and large-scale integrated circuits (LSI's) have realized higher processing speeds and higher degree of integration than ever before. For example, high-performance microprocessors and large-capacity memory chips are rapidly emerging. One of the major driving forces of the development of high performance devices is the progress in the fine-processing technology. One example of such fine-processing technology is the chemical-mechanical polishing (CMP), a technique used in the multilayer interconnection process to planarize an interlayer dielectric, metal plugs and metal wiring.

With regard to metal wiring, attempts have been made to use copper or copper alloy to cope with the problem of wiring delay. In forming copper or copper alloy wiring, trenches are first formed in the interlayer dielectric and, if necessary, a thin barrier film, such as of Ta, is deposited. This is followed by the deposition of copper or copper alloy using the damascene method or other proper techniques. Excessive deposition of copper or copper alloy on top of the interlayer dielectric is then removed by polishing to perform planarization. In this manner, desired wiring is obtained.

One way to planarize copper or copper alloy wiring is to use a polish containing abrasive particles. However, copper or copper alloy in general is a soft material and is susceptible to scratches when treated with the polish alone. This may result in a significant decrease in the product yield. It is also contemplated to use a polish containing an etching agent since such agents can readily dissolve copper. A drawback of this approach comes from the fact that the etching agent etches the surface in recessed regions of the copper deposit as well as in raised regions. Not only does this result in defective planarization of the copper deposit, but it also brings about a phenomenon known as “dishing“where metal wiring has been eaten away.

To prevent such a phenomenon, a metal polish composition disclosed in JP-A HEI 8-83780 and intended for polishing metal film of copper or copper alloy contains hydrogen peroxide, benzotriazole and aminoacetic acid and, optionally, abrasive particles. It is described therein that benzotriazole reacts with the oxidized metal film to form a protective layer, so that the protective layer is the raised regions of the metal deposits that are primarily polished mechanically. In this manner, the planarity of the copper wiring is improved and the occurrence of dishing is reduced.

Another type of metal polish composition disclosed in JP-A HEI 9-55363 contains 2-quinolinecarboxylic acid that reacts with copper to form a copper complex that is hardly soluble in water and is mechanically weaker than copper.

A different type of metal polish composition that contains an amine has also been disclosed. For example, JP-A 2001-303050 describes a polish solution that contains an amine having a long-chain alkyl group, an etching agent and water. This polish solution helps maintain the stable polishing rate of metal film while decreasing the etching rate, so that the dishing of the metal wiring layer is effectively prevented. Polish slurry disclosed in each of JP-A 2001-187877 and JP-A 2001-189296 contains an alkanolamine, an abrasive material, an oxidizing agent and an organic acid.

While the benzotriazole-containing metal polish composition described in JP-A HEI 8-83780 is effective to some extent both in improving the planarity and in preventing dishing, the strong anticorrosive ability of benzotriazole often results in a significant decrease in the polishing rate. On the other hand, the metal polish composition described in JP-A HEI 9-55363 is not appropriate for industrial application since 2-quinolinecarboxylic acid used in the composition is quite expensive.

The amine-containing compositions disclosed in JP-A 2001-303050 have been designed to address the above-described problems by using an amine having a long-chain alkyl group. While these compositions are effective to some extent in decreasing the etching rate while maintaining the polishing rate, the relatively low polishing rate of these compositions makes them less than satisfactory. On the other hand, the polish slurry described in each of JP-A 2001-187877 and JP-A 2001-189296, which contains an alkanolamine, an abrasive material, an oxidizing agent and an organic acid, is intended to minimize the polishing rate of the barrier film, and examples in these publications mentioned that the polishing rate of the metal wiring film was also significantly decreased.

Accordingly, it is an objective of the present invention to provide a metal polish composition that achieves fast polishing while minimizing the etching rate of the metal film and maintaining the planarity of the metal film. It is also an objective of the present invention to provide a method for polishing metal film using the metal polish composition, as well as a method for manufacturing wafers that involves the step of planarizing metal film with the metal polish composition.

### DISCLOSURE OF THE INVENTION

The present invention provides the following items:

(1) A metal polish composition of the present invention contains an amine represented by general formula (1): 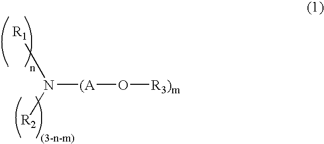
wherein m represents an integer of from 1 to 3 and n represents an integer of from 0 to 2, with m and n being such that (3-n-m) is an integer of from 0 to 2; A represents a straight-chained or branched alkylene, phenylene or substituted phenylene group having 1 to 5 carbon atoms; R1 and R3 each independently represent hydrogen or a substituted or non-substituted hydrocarbon group having 1 to 5 carbon atoms; R3 represents a substituted or non-substituted hydrocarbon group having 1 to 20 carbon atoms; a combination of R1 and R3, a combination of R2 and R3 and a combination of A and R3 can form a ring structure; and R1, R2, R3 and A can individually form a ring structure.

(2) The metal polish composition in item (1) can contain an oxidizing agent.

(3) In the metal polish composition in item (2), the oxidizing agent is hydrogen peroxide.

(4) The metal polish composition in any one of items (1) to (3) further contains an etching agent.

(5) In the metal polish composition in item (4), the etching agent is selected from the group consisting of ammonia, an organic acid, a salt of organic acid, an amino acid and a salt of amino acid.

(6) In the metal polish composition in item (5), the organic acid is at least one selected from the group consisting of acetic acid, lactic acid, malic acid, citric acid, tartaric acid, glycolic acid, oxalic acid and phthalic acid.

(7) The metal polish composition in any one of items (1) to (6) can further contain abrasive particles.

(8) In the metal polish composition in item (7), the abrasive particles are at least one selected from the group consisting of silica particles, alumina particles, ceria particles and organic abrasive particles.

(9) In the metal polish composition in any one of items (1) to (8), the abrasive particles contain primary particles having a particle size of 10 to 100 nm and have a concentration of not more than 20% by mass.

(10) The metal polish composition in any one of items (1) to (9) can contain a compound capable of forming an insoluble complex upon exposure to copper ions.

(11) In the metal polish composition in item (10), the compound is an azole compound.

(12) In the metal polish composition in of item (11), the azole compound is benzotriazole.

(13) In the metal polish composition in any one of items (1) to (12), the amine is at least one selected from the group consisting of methoxypropanol-amine, furfurylamine, tetrahydrofurfurylamine, morpholine, N-substituted morpholine, aminopropylpolyalkyleneglycol, oxazoline and oxazole.

(14) In the metal polish composition in any one of items (1) to (13), the amine has a concentration of 0.01 to 20% by mass.

(15) The metal polish composition in any one of items (1) to (14) has a pH value of 3 to 10.

(16) A polishing method comprises polishing a metal film deposited on a wafer having a recess to cover the recess with the metal polish composition in any one of items (1) to (15).

(17) In the polishing method in item (16), the wafer further has a barrier metal film deposited on top thereof.

(18) In the polishing method in item (16), the metal film is formed of copper or alloy containing copper.

(19) in the polishing method in item (17), the barrier metal film is formed of a tantalum-based metal.

(20) In the polishing method in any one of items (16) to (19), an etching agent having an etching rate suppressed to not more than ⅕ by the amine is used.

(21) A method for producing a planarized wafer comprises polishing a metal film deposited on a wafer having a recess to cover the recess using the metal polish composition in any one of items (1) to (15) to planarize the metal film, thereby producing a planarized wafer.

(22) A method for producing a planarized wafer comprises polishing a metal film deposited on a wafer having a recess to cover the recess utilizing the polishing method in any one of items (16) to (20) to planarize the metal film, thereby producing a planarized wafer.

In the present invention, as described above, addition of a specific amine to a metal polish composition suppresses etching on the surface of a copper plate and enhances the polishing rate to enable a wafer excellent in planarity to be readily produced.

### BEST MODE FOR CARRYING OUT THE INVENTION

In an effort to find a metal polish composition capable of suppressing the etching rate and enhancing the polishing rate, the present inventors have found that the problems encountered heretofore can be effectively eliminated through the use of a metal polish composition containing an amine represented by general formula (1): 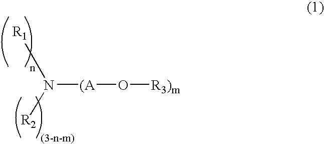
wherein m represents an integer of from 1 to 3 and n represents an integer of from 0 to 2, with m and n being such that (3-n-m) is an integer of from 0 to 2; A represents a straight-chained or branched alkylene, phenylene or substituted phenylene group having 1 to 5 carbon atoms; R1 and R3 each independently represent hydrogen or a substituted or non-substituted hydrocarbon group having 1 to 5 carbon atoms; R3 represents a substituted or non-substituted hydrocarbon group having 1 to 20 carbon atoms; a combination of R1 and R3, a combination of R2 and R3 and a combination of A and R3 can form a ring structure; and R1, R2, R3 and A can individually form a ring structure. This finding has ultimately led the present inventors to complete the present invention.

The metal polish composition of the present invention contains an amine represented by general formula (1) and required to include an ether group within its molecule. Examples of such an amine include alkanoletheramines, such as methoxyethanolamine and methoxypropanolamine; furfuryl-amines, such as furfurylamine, dihydrofurfurylamine, tetra-hydrofurfurylamine and 2,5-dihydro-2,5-dimethoxyfurfuryl-amine; morpholines, such as morpholine, 4-methylmorpholine, methyl-4-morpholinepropionate, 2,6-dimethylmorpholine, 4-(2-chloroethyl)morpholine, 2,5-diethoxy-4-morpholinoaniline, 4-[2-(dimethylamino)ethyl]morpholine, 4-(2-aminoethyl)-morpholine, 4-aminomorpholine, 4-(3-aminopropyl)morpholine, 4-hydroxy-3-(morpholinomethyl)benzoic acid, 4-morpholine-ethanol, 3-morpholino-1,2-propanediol, (4-morpholinyl-methyl)benzotriazole, 4-morpholinecarbonitrile, formyl-morpholine, acryloylmorpholine, polyacryloylmorpholine and 2,2,2-tribromaethylphosphoromorpholinechloridate; amino-propylpolyalkyleneglycol; large cyclic compounds, such as 4,7,10-trioxa-1,13-tridecane-diamine, 2-(aminomethyl) 15-crown-5,1-aza-15-crown-5,1-aza-18-crown-6,5,6-benzo-4,7,13,16,21,24-hexaoxa-1,10-diaza-bicyclo[8.8.8]hexacosane, 4,7,13,16,21,24-hexaoxa-1,10-di-azabicyclo[8.8.8]hexacosane-N,N′-dibenzyl-1,4,10,13-tetra-oxa-7,16-diazacyclooctadecane, 4,7,13,16,21-pentaoxa-1,10-diazabicyclo[8.8.5]tricosane and 1-aza-3,7-dioxabicyclo-[3.3.0]octane-5-methanol; oxazolines, such as 2-methyl-2-oxazoline, 2-phenyl-2-oxazoline, 2-ethyloxazoline, 2,4,4-trimethyl-2-oxazoline; oxazoles, such as benzoxazole, 2-phenylbenzoxazole, 2,4,5-trimethyloxazole, 2-chlorobenzoxazole, 5-chloro-2-methylbenzoxazole, 2,2-bis[(4S)-4-benzyl-2-oxazoline, 2,5-bis(4-biphenylyl)-1,3,4-oxadiazole, benzoxazolinone, 5-chloromethyl-2-oxazolidinone, 3-methyl-2-oxazolidinone, 4,4-dimethyloxazolidine, 2-oxazolidone and 2,5-oxazolidinedione; 2-butoxypyridine; 1-[2-(4-bromophenoxy)ethyl]pyrrolidine; 2,2-dimethyl-1,3-dioxolane-4-methanamine; 2-methylamino-methyl-1,3-dioxolane; 1,4-dioxa-8-azaszpiro[4.5]decane; and nefopan.

Preferably, the amine for use in the present invention is contained in the metal polish composition in an amount of 0.01 to 20% by mass (concentration), more preferably in an amount of 0.05 to 10% by mass, and particularly preferably in an amount of 0.1 to 10%. by mass. If the amount is too small, then the ability of the amine to suppress etching will be insignificant, whereas the amine present at an excessively high concentration will result in a decrease in the polishing rate of copper. Too high a concentration of the amine is also economically unfavorable.

Preferably, the metal polish composition of the present invention contains an oxidizing agent that acts to oxidize copper or copper alloy and to thereby increase the polishing rate. Examples of the oxidizing agent include oxygen; ozone; hydrogen peroxide: alkylperoxides, such as t-butylhydroperoxide and ethylbenzenehydroperoxide; peracids, such as peracetic acid and perbenzoic acid; potassium permanganate; potassium iodate; and ammonium persulfate. Among these oxidizing agents, hydrogen peroxide, free of metal elements, is particularly preferred.

Preferably, the oxidizing agent is contained in the metal polish composition in an amount of 0.01 to 30% by mass and more preferably, in an amount of 0.1 to 20% by mass. Too small an amount of the oxidizing agent produces insufficient effect, whereas too large an amount not only wastes the oxidizing agent but may also reduce the polishing rate.

Preferably, the metal polish composition of the present invention contains an etching agent. The etching agent is contained to facilitate the polishing and help maintain stable polishing. Examples of the etching agent include ammonia; carboxylic acids, such as formic acid, acetic acid, propionic acid, butyric acid, n-haxanoic acid, n-octanoic acid, benzoic acid, glycolic acid, salicylic acid, oxalic acid, malonic acid, succinic acid, glutaric acid, adipic acid, pimelic acid, maleic acid, phthalic acid, lactic acid, malic acid, tartaric acid, citric acid and glycolic acid; phenols, such as phenol and catechol; and amino acids, such as glycine, glycylglycine, alanine, phenylalanine, serine, tryptophan, aspartic acid, lysine and glutamic acid.

These etching agents may be used either independently or as a mixture of two or more agents. Preferably, the etching agent is contained in the metal polish composition in an amount of 0.01 to 10% by mass. The amount of the etching agent that is 0.01% by mass or less will result in an insufficient polishing rate, whereas the etching rate of copper or copper alloy will be too fast to properly carry out planarization or to suppress the occurrence of dishing if the amount exceeds 10% by mass or more.

The metal polish composition of the present invention, when added with an amine, can decrease the etching rate to ⅕ and also to 0 mm/min if two or more different amine species combined in due consideration of their mixing ratios are added.

While the metal polish composition of the present invention may be used without adding abrasive particles, it may contain abrasive particles for the purpose of, for example, achieving a sufficient polishing rate. Examples of the abrasive particles include silica, alumina, ceria and organic abrasive particles. In order to prevent the occurrence of dishing or scratches, the amount of the abrasive particles is preferably kept to 30% by mass or less, more preferably 20% by mass or less, of the amount of the metal polish composition.

The abrasive particles usable in the present invention are those containing primary particles having a particle size of 1 nm to several um, preferably 5 to 200 nm, and more preferably 10 to 100 nm. The particle size of not more than 1 nm will result in a decrease in the polishing rate, and that of exceeding several Jim in the formation of scratches.

For the purpose of providing proper polishing, the metal polish composition of the present invention may further contain an anticorrosive agent or an agent for forming a protective film for metal in addition to the amine of the present invention. These components may be a compound that can form an insoluble complex upon exposure to copper ions. Preferred examples of such components include azoles, such as benzimidazole-2-thiol, 2-[2-(benzothiazolyl)]-thiopropionic acid, 2-[2-(benzothiazolyl)thiobutyric acid, 2-mercaptobenzothiazole, 1,2,3-triazole, 1,2,4-triazole, 3-amino-1H-1,2,4-triazole, benzotriazole, 1-hydroxybenzo-triazole, 1-dihydroxypropylbenzotriazole, 2,3-dicarboxy-propylbenzotriazole, 4-hydroxybenzotriazole, 4-carboxyl-1H-benzotriazole, 4-methoxycarbonyl-1H-benzotriazole, 4-butoxy-carbonyl-1H-benzotriazole, 4-octyloxycarbonyl-1H-benzo-triazole, 5-hexylbenzotriazole, N-(1,2,3-benzotriazolyl-1-methyl)-N-(1,2,4-triazolyl-1-methyl)-2-ethylhexylamine, tryltriazole, naphthotriazole, bis[(1-benzo-triazolyl)-methyl]phosphonic acid, benzimidazole and tetrazole; and salts thereof. The amount of the anticorrosive agent or the film-forming agent is preferably 5% by mass or less with respect to the amount of the metal polish composition. It is more preferably 1% by mass or less.

An inorganic acid or salts thereof, or an alkali, may be added to the metal polish composition of the present invention in an amount that does not affect the performance or the physical properties of the composition. These components are added to help maintain stable polishing performance of the metal polish composition or to serve as a pH conditioner or a buffer.

Examples of the inorganic acid include carbonic acid, phosphoric acid, sulfuric acid, hydrochloric acid and nitric acid. Examples of the salts of the inorganic acid include ammonium salts and potassium salts. Examples of the alkali include sodium hydroxide, potassium hydroxide, potassium carbonate, potassium bicarbonate and ammonium bicarbonate. Preferably, the inorganic acid, salt or alkali is added to the metal polish composition in an amount of 5% by mass or less, more preferably 1% by mass or less, with respect to the amount of the metal polish composition.

When necessary, the metal polish composition of the present invention may further contain a water-soluble polymer or a surfactant. Examples of the water-soluble polymer include polyacrylic acid, polymethacrylic acid or ammonium salts thereof, polyisopropylacrylamide, poly-dimethylacrylamide, polymethacrylamide, polymethoxyethylene, polyvinylalcohol, hydroxyethylcellulose, carboxymethyl-cellulose, carboxyethylcellulose and polyvinylpyrrolidone. The surfactant may be any of cationic, anionic and nonionic surfactants. Examples of the cationic surfactant include aliphatic amine salts and aliphatic ammonium salts.

Examples of the anionic surfactant include carboxylates, such as fatty acid soap and alkylether-carboxylates; sulfonates, such as alkylbenzenesulfonates and alkylnaphthalenesulfonates; sulfate esters, such as sulfate esters of higher alcohols and alkylethersulfate; and phosphate esters, such as phosphate esters of alkyls.

Examples of the nonionic surfactant includes those of ether type, such as polyoxyethylenealkylethers; those of ether-ester type, such as polyoxyethyleneether of glycerol esters; and those of ester type, such as fatty acid esters of polyethyleneglycol, glycerol esters and sorbitan esters.

The amount of the water-soluble polymer and the surfactant is preferably 5% by mass or less, more preferably 1% by mass or less, of the metal polish composition.

The metal polish composition of the present invention can be used in the pH range of 2 to 12 and, preferably, in the pH range of 3 to 10. The above-described etching agents, inorganic acids or salts of the inorganic acids may be used to adjust the pH of the metal polish composition, or oxides or hydroxides of alkali metals or alkali earth metals may be used for this purpose.

The metal polish composition of the present invention can be used at a temperature in the range of 0 to 70° C. When the temperature is low, the polishing rate becomes low. When the temperature is high, the etching rate becomes excessively high. Therefore, it is preferably in the range of 10 to 50° C., more preferably in the range of 15 to 40° C.

Examples of metals that can be polished by the metal polish composition of the present invention include aluminum, copper, tungsten, nickel, tantalum, tantalum nitride, metals of platinum family, such as ruthenium and platinum, and alloys thereof.

The metal polish composition of the present invention can be applied to copper or copper alloy that can be used to form wires of multilayer interconnection. Such metal is deposited on a wafer that includes recesses in such a manner that the metal fills the recesses.

According to a polishing method of the present invention using the metal polish composition, a metal film deposited on a wafer is polished by pushing the wafer against a polishing pad on a polishing table and moving the polishing table and the wafer relative to each other while the metal polish composition of the present invention is fed to the polishing pad.

While the pressure under which the wafer having the metal film is pushed against the polishing pad is optionally selected, it is generally in the range of 0.98 to 98 Kpa (10 to 1000 gm/cm²) and preferably in the range of 4.9 to 49 Kpa (50 to 500 gf/cm²)

An ordinary polishing apparatus, which includes a holder for holding a semiconductor wafer in place and a polishing table with a polishing pad bonded thereto, can be used in the present invention. Ordinary non-woven fabric or foamed polyurethane material may be used as the polishing pad in the present invention. Using a pump or other proper means, the metal polish composition of the present invention is continuously fed onto the polishing pad on a polishing table. In doing so, the metal polish composition may be provided in the form of a single solution that contains all of the necessary components. Otherwise, considering the stability of the solution, it may be separately fed onto the polishing pad in the forms of a hydrogen peroxide solution and other solutions. When it is desired to feed the composition in the form of two or more separate solutions, the solutions may be combined to form a single solution immediately upstream of the polishing pad or they may be individually fed onto the polishing pad.

In this manner, wafers with a planarized metal film can be fabricated. Specifically, this process is carried out in the following manner. First, trenches and openings for wiring are formed in the interlayer dielectric deposited on a wafer, and a thin barrier film is deposited on top of the insulation film. Using plating or other proper techniques, a metal film for the metal wiring, such as a copper film, is then deposited on the wafer to fill the trenches and the openings. This metal film is then planarized by polishing and, if necessary, further polishing down to the barrier film and the interlayer dielectric. This completes a wafer with a planarized metal film. The term “interlayer dielectric” used herein is meant to include those formed of inorganic materials, such as silicon oxide, HSQ and MSQ as well as those formed of organic materials, such as benzocyclobutene. A low k interlayer dielectric including holes may also be used for this purpose.

The present invention will now be described in further detail with reference to examples, which are not intended.to limit the scope of the invention in any way.

The polishing rate test was conducted under the following conditions.

Wafer: 4×4 cm silicon wafers with copper film

Relative speed between wafer and polishing plate: 54 m/min

Polishing pressure: 30.1 Kpa (307 gf/cm²)

Polishing pad: IC1000/SUBA400 manufactured by Rodel Nitta Co., Ltd.

Feeding rate of polish composition: 13 ml/min

Measurement of polishing rate: determined as the difference between the surface resistivity of copper before polishing and that after the polishing.

The etching test was conducted by immersing 2 cm×2 cm copper film in the metal polish composition, and the etching rate per minute was determined as the decrease in the amount of the copper plate.

The actual polishing performance of the metal polish composition was evaluated by polishing patterned wafers under the following conditions.

Wafer: Tantalum film was used as a barrier film, and 4×4 cm pieces of silicon wafer with an 800 nm deep trench and a 1600 nm thick copper film were used.

Relative speed between wafer and polishing plate: 54 m/min

Polishing pressure: 30.1 Kpa (307 gf/cm²)

Polishing pad: IC1000/SUBA400 manufactured by Rodel Nitta Co., Ltd.

Feeding rate of polish composition: 13 ml/min

Measurement of step height: Using a contact step height meter, the height of the step was measured at 100 μm/100 μm line/space.

### EXAMPLES 1 AND 2, AND COMPARATIVE EXAMPLE 1

Tetrahydrofurfurylamine used as amine, malic arid as an etching agent and hydrogen peroxide as an oxidizing agent were added in the amounts shown in Table 1 below to prepare metal polish compositions. A test for examining their ability to suppress etching was performed. A metal polish composition was prepared without adding amine and subjected to the same test.

The results for each composition are as shown in Table 1 below. While Comparative Example 1 without adding amine exhibited a high etching rate, Examples with amine added exhibited significant suppression of the etching rate. In the case of Example 2, the etching rate was substantially zero nm/min.

TABLE 1

| | Ex 1 | Ex 2 | Com Ex 1 |
|---|---|---|---|
| Tetrahydrofurfurylamine | 0.3 | 1 | — |
| (% by mass) | | | |
| Malic acid (% by mass) | 1 | 1 | 1 |
| hydrogen peroxide (% by | 2 | 2 | 2 |
| mass) | | | |
| pH | 4.5 | 8.8 | 2.2 |
| Etching rate (nm/min) | 3 | 0 | 105 |

### EXAMPLES 3 THROUGH 7, AND COMPARATIVE EXAMPLES 2 AND 3

Different types of the metal polish composition having different chemical compositions, as shown in Table 2 below, were prepared. An amine, colloidal silica with primary particles having a particle size of 30 nm used as abrasive particles, and an organic acid were dissolved in water, followed by the addition of an oxidizing agent. By further adding a pH conditioner, the pH of the mixture was conditioned to a predetermined value. Each metal polish composition was examined for the polishing rate and the etching rate. The results are shown in Table 2 below.

Comparative Example 2 free of amine exhibited a relatively low polishing rate, while the polishing rate of Comparative Example 3 containing propanolamine showed an improvement of some degree though it was still not high enough to be satisfactory. In contrast, no etching was observed and the polishing rate was significantly improved in Examples 3 and 4 each containing one of the amines for the present invention.

On the other hand, Example 5 containing no ammonia to adjust the pH did not give rise to the occurrence of etching while showing an improved polishing rate.

Example 6 containing malic acid as an organic acid in place of lactic acid showed a further improved polishing rate.

Benzotriazole serving as an anticorrosive agent was added to Example 7. Example 7 with benzotriazole added exhibited a stable polishing performance though the polishing rate was decreased to some degree.

TABLE 2

| | | Ex 3 | Ex 4 | Ex 5 | Ex 6 | Ex 7 | Comp Ex 2 | Comp Ex 3 |
|---|---|---|---|---|---|---|---|---|
| amine | methoxypropylamine | 0.3 | | | | | | |
| (% by mass) | tetrahydrofurfuryl | | 0.3 | 0.3 | 0.3 | 0.3 | | |
| | amine | | | | | | | |
| | propanolamine | | | | | | | 0.3 |
| anti-corrosive | benzotriazole | | | | | 0.01 | | |
| agent | | | | | | | | |
| (% by mass) | | | | | | | | |
| oxidizing agent | hydrogen peroxide | 2 | 2 | 2 | 2 | 2 | 2 | 2 |
| (% by mass) | | | | | | | | |
| abrasive | colloidal silica | 1 | 1 | 1 | 1 | 1 | 1 | 1 |
| particles | | | | | | | | |
| (% by mass) | | | | | | | | |
| organic acid (% by mass) | | lactic | lactic | lactic | malic | lactic | lactic | lactic |
| | | acid 3 | acid 3 | acid 3 | acid 1 | acid 1 | acid 3 | acid 3 |
| pH conditioner | | ammonia | ammonia | | ammonia | ammonia | ammonia | ammonia |
| pH | | 9 | 9 | 4.5 | 9.6 | 9 | 9 | 9 |
| Polishing | | 30.1 | 30.1 | 30.1 | 30.1 | 30.1 | 30.1 | 30.1 |
| pressure | | KPa | KPa | KPa | KPa | KPa | KPa | KPa |
| | | (307 gf/cm²) | (307 gf/cm²) | (307 gf/cm²) | (307 gf/cm²) | (307 gf/cm²) | (307 gf/cm²) | 307 gf/cm²) |
| Polishing rate | (nm/ [symbol] ) | 502 | 592 | 478 | 929 | 384 | 314 | 412 |
| Etching rate | (nm/ [symbol] ) | 0 | 0 | 4 | 40 | 0 | 0 | 0 |

### EXAMPLE 8

An aqueous solution containing tetrahydrofurfurylamine (1% by mass), benzotriazole (0.015% by mass), acetic acid (1% by mass), colloidal silica with primary particles having a particle size of 30 nm (1% by mass) and hydrogen peroxide (2% by mass) was prepared, and the pH of the solution was adjusted to 9 using ammonia. The polishing rate and the etching rate were 500 nm/min and 0 nm/min, respectively. This composition was used to polish a patterned wafer to evaluate the actual polishing performance of the polish composition. Polishing was continued until the tantalum barrier film was exposed. The height of the resulting step formed in the wafer was determined to be 30 nm. The polish composition showed a high ability to reduce the formation of steps while causing less dishing. No scratch was observed on the wafer.

### INDUSTRIAL APPLICABILITY

By taking advantage of particular types of amine, not only can the polish composition of the present invention effectively prevent the surface of copper film from being etched, but it also permits a significant improvement in the polishing rate. In addition, the particular amine used in the present invention, in combination with an anticorrosive agent, offers a high ability to reduce the formation of steps while giving rise to less dishing. Furthermore, the polishing method and the wafer-production method of the present invention facilitate the production of wafers with improved planarity.

1. A metal polish composition containing an amine represented by general formula (1): 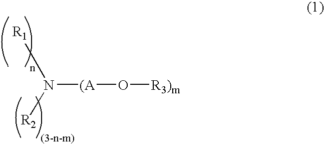
wherein m represents an integer of from 1 to 3 and n represents an integer of from 0 to 2, with m and n being such that (3-n-m) is an integer of from 0 to 2; A represents a straight-chained or branched alkylene, phenylene or substituted phenylene group having 1 to 5 carbon atoms; R1 and R3 each independently represent hydrogen or a substituted or non-substituted hydrocarbon group having 1 to 5 carbon atoms; R3 represents a substituted or non-substituted hydrocarbon group having 1 to 20 carbon atoms; at least one of R1 and R2, together with R3, can form a ring structure; and A can form a ring structure in conjunction with R3.

2. The metal polish composition according to claim 1,further containing an oxidizing agent.

3. The metal polish composition according to claim 2, wherein the oxidizing agent is hydrogen peroxide.

4. The metal polish composition according to any one of claims 1 to 3, further containing an etching agent.

5. The metal polish composition according to claim 4, wherein the etching agent is selected from the group consisting of ammonia, an organic acid, a salt of organic acid, an amino acid and a salt of amino acid.

6. The metal polish composition according to claim 5, wherein the organic acid is at least one selected from the group consisting of acetic acid, lactic acid, malic acid, citric acid, tartaric acid, glycolic acid, oxalic acid and phthalic acid.

7. The metal polish composition according to claim 1, further containing a polishing agent.

8. The metal polish composition according to claim 7, wherein the polishing agent is at least one selected from the group consisting of silica, alumina, ceria and organic abrasive particles.

9. The metal polish composition according to claim 7, wherein the polishing agent contains primary particles having a particle size of 10 to 100 nm and has a concentration of not more than 20% by mass.

10. The metal polish composition according to claim 1, further containing a compound capable of forming an insoluble complex upon exposure to copper ions.

11. The metal polish composition according to claim 10, wherein the compound is an azole compound.

12. The metal polish composition according to claim 11, wherein the azole compound is benzotriazole.

13. The metal polish composition according to claim 1, wherein the amine is at least one selected from the group consisting of methoxypropanol-amine, furfurylamine, tetrahydroffurfurylamine, morpholine, N-substituted morpholine, aminopropylpolyalkyleneglycol; and oxazoline.

14. The metal polish composition according to claim 1, wherein the amine has a concentration of 0.01 to 20% by mass.

15. The metal polish composition according to claim 1, wherein it has a pH value of 3 to 10.

16. A polishing method comprising polishing a metal film deposited on a wafer having a recess to cover the recess with the metal polish composition according to claim 1.

17. The polishing method according to claim 16, wherein the wafer further has a barrier metal film deposited on top thereof.

18. The polishing method according to claim 16, wherein the metal film is formed of copper or alloy containing copper.

19. The polishing method according to claim 17, wherein the barrier metal film is formed of a tantalum-based metal.

20. The metal polish composition according to claim 16, wherein the etching agent has an etching rate suppressed to not more than ⅕ by the amine.

21. A method for producing a planarized wafer comprising polishing a metal film deposited on a wafer having a recess to cover the recess using the metal polish composition according to claim 1 to planarize the metal film, thereby producing a planarized wafer.

22. A method for producing a planarized wafer comprising polishing a metal film deposited on a wafer having a recess to cover the recess utilizing the polishing method according to claim 16 to planarize the metal film, thereby producing a planarized wafer.

23. The metal polish composition according to claim 13, wherein the amine is methoxypropylamine or tetrahydrofurfurylamine.

24. The metal polish composition according to claim 23, wherein the amine is tetrahydrofurfurylamine.
